(19) United States
(12) Patent Application Publication
(10) Pub. No.: US 2013/0099834 A1
(43) Pub. Date: Apr. 25, 2013

(54) RAMP SIGNAL GENERATION CIRCUIT AND RAMP SIGNAL ADJUSTMENT CIRCUIT

(71) Applicant: TDK Corporation, Tokyo (JP)

(72) Inventors: Kazunori OSHIMA, Tokyo (JP); Hironobu MASUOKA, Tokyo (JP); Mitsuyuki TSUJISAKA, Tokyo (JP); Yukiharu MIYAOKA, Tokyo (JP)

(73) Assignee: TDK CORPORATION, Tokyo (JP)

(21) Appl. No.: 13/654,513

(22) Filed: Oct. 18, 2012

(30) Foreign Application Priority Data
Oct. 20, 2011 (JP) 2011-231072

(51) Int. Cl. H03K 4/06

(52) U.S. Cl. 327/131

(57) ABSTRACT

A ramp signal generation circuit comprises a first input terminal that receives a clock signal, a plurality of second input terminals that receive high-level or low-level signals, and a discharge and charge circuit that discharges and charges the capacitor and that outputs a ramp signal corresponding to a voltage generated by the capacitor. The discharge and charge circuit comprises a discharge circuit that discharges the capacitor, and a charge circuit that is configured with a plurality of paired resistors and rectifying elements connected between the capacitor and the plurality of second input terminals. The discharge and charge circuit selects at least one of the plurality of second input terminals so as to change a current value for charging the capacitor by inputting the high-level signal to the selected one of the plurality of second input terminals.

### CROSS-REFERENCE TO RELATED APPLICATION

This application claims priority to Japanese Patent Application No. 2011-231072 filed Oct. 20, 2011 which is hereby expressly incorporated by reference herein in its entirety.

### BACKGROUND

The present invention relates to a ramp signal generation circuit and a ramp signal adjustment circuit that can be applied to a power supply device and a light emitting element drive device. Specifically, the present invention relates to a ramp signal generation circuit and a ramp signal adjustment circuit that generate a ramp signal in accordance with a clock signal.

Japanese Patent Publication No. 2004-96815 discloses a power supply device, such as a DC/DC converter, that performs pulse width modulation (PWM) control for a switching element in accordance with a PWM signal generated according to an operation clock of a digital circuit.

A frequency of the PWM signal may be changed according to an operation state of the power supply device. For example, when a load is light, a frequency of the PWM signal decreases to lower an operation loss of the switching element.

When a PWM signal is generated based on a ramp signal, a frequency of the PWM signal is determined by a frequency of the ramp signal. Further, when the PWM signal is generated by using the ramp signal that is synchronized with an operation clock signal as a clock signal from a digital circuit, the PWM signal that is synchronized with the operation clock signal is generated. In general, a serration-shaped or sawtooth wave ramp signal is generated by charging and discharging a capacitor included in a ramp signal generation circuit. A peak voltage value (a peak value of a charged voltage) of the ramp signal is determined by a charging time and a slope of the charge voltage increase that depends on values of a charge current for the capacitor. Accordingly, when the slope of the charged voltage increase is constant, the charging time lengthens, and the peak voltage value (a peak value of the charged voltage) heightens.

FIG. 10 shows an example of a conventional ramp signal generation circuit 100. In FIG. 10, the ramp signal generation circuit 100 is configured with a switching element Q2, capacitors C2, C3, a diode D2, and resistors R4, R5 and R6. Specifically, one end of the capacitor C2 is connected to an input terminal 21 for a clock signal S1. Another end of the capacitor C2 is connected to a cathode of the diode D2 and to one end of the resistor R4. Another end of the resistor R4 is connected to one end of the resistor R5 and to a base of the switching element Q2 that is an NPN-type transistor. Further, one end of the resistor R6 is connected to a line of an operation voltage Vcc from an internal power supply (not shown). Another end of the resistor 6 is connected to a collector of the switching element Q2 and to one end of the capacitor C3. Further, an anode of the diode D2, another end of the resistor R5, an emitter of the switching element Q2, and another end of the capacitor C3 are commonly connected to a ground line. Lastly, the collector of the switching element Q2 that is a node between the resistor R6 and the capacitor C3 is connected to an output terminal 22 for a ramp signal S2. The ramp signal generation circuit 100 is configured with the above structure.

In the ramp signal generation circuit 100 shown in FIG. 10, the slope of the charged voltage increase is determined by a time constant that is obtained as the product of a resistor value of the resistor R6 and a capacitance value of the capacitor C3. The clock signal S1 from the input terminal 21 becomes a differential signal S10 that is processed with waveform shaping to change it to a trigger signal through the capacitor C2. The differential signal S10 generated at another end of the capacitor C2 is processed with waveform shaping by the diode D2 so as to generate the trigger signal only at a positive side. After a voltage value of the differential signal S10 is reduced (divided) by the resistors R4, R5, the differential signal S10 is given to the base of the switching element Q2. When the voltage level of the differential signal S10 increases, a status between the emitter and the collector of the switching element Q2 is an ON state. As a result, the capacitor C3 is discharged. On the other hand, when the voltage level of the differential signal S10 decreases, a status between the emitter and the collector of the switching element Q2 is an OFF state. As a result, the capacitor C3 is charged by supplying the power supply voltage Vcc to the capacitor C3 through the resistor R6. That is, after the discharge of the capacitor C3 is performed in synchronization with a rising edge of the clock signal S1, the charging of the capacitor C3 starts. Therefore, the ramp signal S2 is synchronized with the clock signal S1. A frequency of the ramp signal S2 can be changed by changing a frequency of the clock signal S1.

FIG. 11 respectively shows waveforms of the differential signal S10 and the ramp signal S2 when the clock signal S1 is 250 kHz and when the clock signal S1 is 500 kHz. As shown in FIG. 11, in the conventional ramp signal generation circuit 100, when a cycle of the clock signal S1 becomes longer, the peak voltage value of the ramp signal S2 becomes higher and the amplitude of the ramp signal S2 becomes larger. Similarly, when the cycle of the clock signal S1 becomes shorter, the peak voltage value of the ramp signal S2 becomes lower and the amplitude of the ramp signal S2 becomes smaller. However, it is preferred that the peak voltage value (a peak value of the charged voltage) of the ramp signal S2 is constant even when the cycle (the period of charging time) of the ramp signal S2 becomes longer.

### SUMMARY

An object of the present invention is to provide a ramp signal generation circuit and a ramp signal adjustment circuit in which a peak voltage value of a ramp signal is not changed even though a cycle (frequency) of the ramp signal is changed.

One aspect of a ramp signal generation circuit according to the present invention includes: a first input terminal that receives a clock signal; a plurality of second input terminals that receive high-level or low-level signals, respectively, in accordance with a cycle of the clock signal; a capacitor; and a discharge and charge circuit that discharges and charges the capacitor and that outputs a ramp signal corresponding to a voltage generated by the capacitor. The discharge and charge circuit includes a discharge circuit that discharges the capacitor in synchronization with the clock signal, and a charge circuit that is configured with a plurality of paired resistors and rectifying elements connected between the capacitor and the plurality of second input terminals. The charge circuit charges the capacitor through the resistor and the rectifying element. The discharge and charge circuit selects at least one of the plurality of second input terminals so as to change a value of a charge current for charging the capacitor by inputting the high-level signal to the selected one of the plurality of second input terminals.

In the above ramp signal generation circuit according to the present invention, at least one of the plurality of second input terminals is selected in accordance with a cycle of the clock signal that is input to the first input terminal. Then, the high-level signal is input to the selected at least one of the plurality of second input terminals. Because the discharge circuit discharges the capacitor in synchronization with the clock signal, a frequency of the ramp signal corresponds to a frequency of the clock signal. In the charge circuit, a value of a charge current for charging the capacitor is changed so as to make a peak voltage value of the ramp signal constant regardless of the cycle of the clock signal by switching the pair of resistors and rectifying elements in which the charge current flows. As a result, it is possible to provide the ramp signal generation circuit in which the peak voltage value of the ramp signal is not changed even though the cycle of the ramp signal is changed.

Another aspect of a ramp signal generation circuit according to the present invention includes: a first input terminal that receives a clock signal; a plurality of second input terminals that receive high-level or low-level signals, respectively, in accordance with a cycle of the clock signal; a capacitor; and a discharge and charge circuit that discharges and charges the capacitor and that outputs a ramp signal corresponding to a voltage generated by the capacitor. The discharge and charge circuit includes a discharge circuit that discharges the capacitor in synchronization with the clock signal, and a charge circuit that is configured with a plurality of paired resistors and switching elements connected between the capacitor and a power source voltage line. The charge circuit charges the capacitor through one of the resistors and one of the switching elements. The discharge and charge circuit selects at least one of the plurality of second input terminals so as to change a value of a charge current for charging the capacitor through an ON and OFF operation of the switching elements by inputting the high-level signal to the selected one of the plurality of second input terminals.

In the above ramp signal generation circuit according to the present invention, at least one of the plurality of second input terminals is selected in accordance with a cycle of the clock signal that is input to the first input terminal. Then, the high-level signal is input to the selected at least one of the plurality of second input terminals. Because the discharge circuit discharges the capacitor in synchronization with the clock signal, a frequency of the ramp signal corresponds to a frequency of the clock signal. In the charge circuit, a value of a charge current for charging the capacitor is changed so as to make a peak voltage value of the ramp signal constant regardless of the cycle of the clock signal by switching the pair of resistors and switching elements in which the charge current flows. As a result, it is possible to provide the ramp signal generation circuit in which the peak voltage value of the ramp signal is not changed even though the cycle of the ramp signal is changed.

One aspect of a ramp signal adjustment circuit according to the present invention includes: a clock signal generation circuit that generates a clock signal by dividing a base clock signal; a signal output circuit that has a plurality of terminals and that outputs high-level or low-level signals from each of the plurality of terminals; a capacitor; and a discharge and charge circuit that discharges and charges the capacitor and that outputs a ramp signal corresponding to a voltage generated by the capacitor. The discharge and charge circuit includes a discharge circuit that discharges the capacitor in synchronization with the clock signal, and a charge circuit that is configured with a plurality of paired resistors and rectifying elements connected between the capacitor and the plurality of terminals. The charge circuit charges the capacitor through one of the resistors and one of the rectifying elements. The discharge and charge circuit selects at least one of the plurality of terminals so as to change a value of a charge current for charging the capacitor by inputting the high-level signal to the selected one of the plurality of terminals.

In the above ramp signal adjustment circuit according to the present invention, at least one of the plurality of terminals is selected in accordance with a cycle of the clock signal that is generated in the clock signal generation circuit. Then, the high-level signal is input to the selected at least one of the plurality of terminals. Because the discharge circuit discharges the capacitor in synchronization with the clock signal, a frequency of the ramp signal corresponds to a frequency of the clock signal. In the charge circuit, a value of a charge current for charging the capacitor is changed so as to make a peak voltage value of the ramp signal constant regardless of the cycle of the clock signal by switching the pair of resistors and rectifying elements in which the charge current flows. As a result, it is possible to provide the ramp signal adjustment circuit in which the peak voltage value of the ramp signal is not changed even though the cycle of the ramp signal is changed.

Another aspect of a ramp signal adjustment circuit according to the present invention includes: a clock signal generation circuit that generates a clock signal by dividing a base clock signal; a signal output circuit that has a plurality of terminals and that outputs high-level or low-level signals from each of the plurality of terminals; a capacitor; and a discharge and charge circuit that discharges and charges the capacitor and that outputs a ramp signal corresponding to a voltage generated by the capacitor. The discharge and charge circuit includes a discharge circuit that discharges the capacitor in synchronization with the clock signal, and a charge circuit that is configured with a plurality of paired resistors and switching elements connected between the capacitor and a power source voltage line. The charge circuit charges the capacitor through one of the resistors and one of the switching elements. The discharge and charge circuit selects at least one of the plurality of terminals so as to change a value of a charge current for charging the capacitor through an ON and OFF operation of the switching elements by inputting the high-level signal to the selected one of the plurality of terminals.

In the above ramp signal adjustment circuit according to the present invention, at least one of the plurality of terminals is selected in accordance with a cycle of the clock signal that is generated in the clock signal generation circuit. Then, the high-level signal is input to the selected at least one of the plurality of terminals. Because the discharge circuit discharges the capacitor in synchronization with the clock signal, a frequency of the ramp signal corresponds to a frequency of the clock signal. In the charge circuit, a value of a charge current for charging the capacitor is changed so as to make a peak voltage value of the ramp signal constant regardless of the cycle of the clock signal by switching the pair of resistors and switching elements in which the charge current flows. As a result, it is possible to provide the ramp signal adjustment circuit in which the peak voltage value of the ramp signal is not changed even though the cycle of the ramp signal is changed.

### BRIEF DESCRIPTION OF THE DRAWINGS

FIG. 1 is a circuit diagram of a power supply device according to a first embodiment of the present invention.

FIG. 2 is a circuit diagram of a ramp signal generation circuit of the power supply device shown in FIG. 1.

FIG. 3 is a circuit diagram of a pulse control circuit of the power supply device shown in FIG. 1.

FIG. 4 is a timing diagram of each part of the power supply device shown in FIG. 1.

FIG. 5 is a timing diagram of each part of the ramp signal generation circuit shown in FIG. 2.

FIG. 6 is a circuit diagram of a power supply device according to yet another embodiment. The power supply device shown in FIG. 6 is an alternative example of the power supply device shown in FIG. 1.

FIG. 7 is a circuit diagram of a pulse control circuit of the power supply device shown in FIG. 6. The pulse control circuit shown in FIG. 7 is an alternative example of the pulse control circuit shown in FIG. 3.

FIG. 8 is a timing diagram of each part of the power supply device shown in FIG. 6.

FIG. 9 is a circuit diagram of a ramp signal generation circuit according to yet another embodiment. The ramp signal generation circuit shown in FIG. 9 is an alternative example of the ramp signal generation circuit shown in FIG. 2.

FIG. 10 is a circuit diagram of a conventional ramp signal generation circuit.

FIG. 11 is a timing diagram of each part of the ramp signal generation circuit shown in FIG. 10.

### DESCRIPTION OF EXEMPLARY EMBODIMENTS

A ramp signal generation circuit and a ramp signal adjustment circuit according to embodiments of the present invention will be explained below with reference to the drawings.

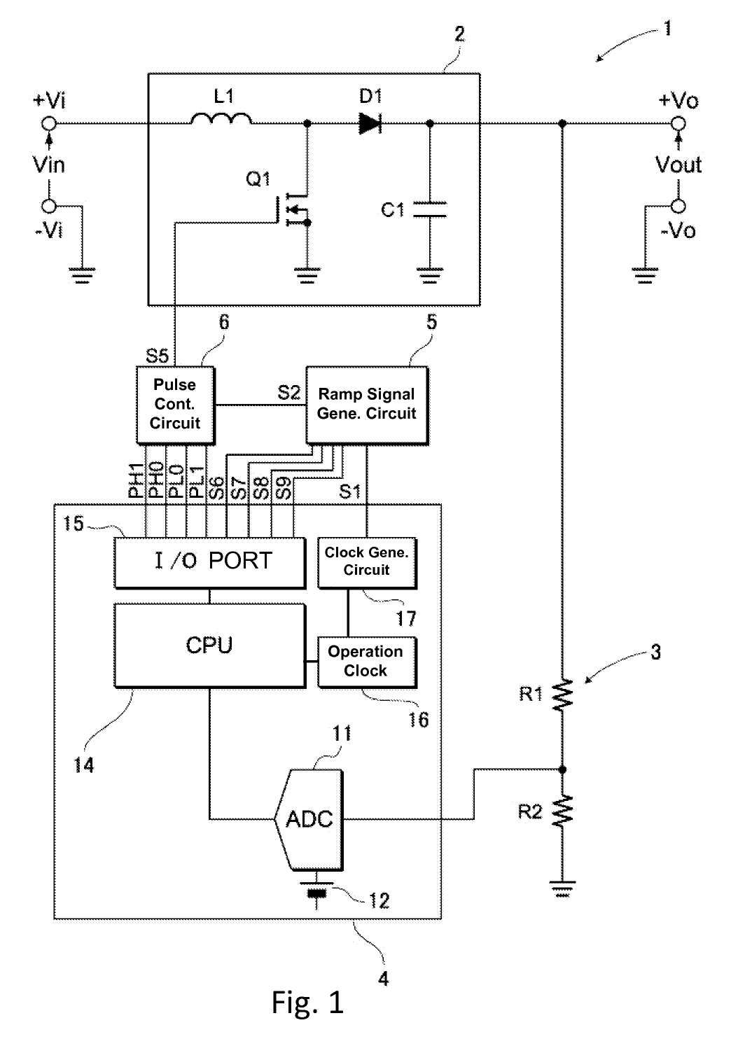

FIG. 1 shows a circuit diagram of a power supply device according to a first embodiment of the present invention. The power supply device according to the first embodiment has a configuration of a constant voltage output circuit block 1 in which an output voltage Vout is controlled as a stable voltage. The constant voltage output circuit block 1 is configured with a converter 2 that is an object to be controlled, a voltage detection circuit 3 that forms a voltage feedback loop for the converter 2, a microprocessor 4, a ramp signal generation circuit 5, and a pulse control circuit 6. Note that the converter 2 shown in FIG. 1 is a step-up type converter.

The converter 2 converts a direct current input voltage Vin, which is applied between input terminals +Vi and −Vi, to a direct current output voltage Vout and supplies the direct current output voltage Vout to output terminals +Vo and −Vo. A load (not shown) is connected between the output terminals +Vo and −Vo. The converter 2 is configured with a step-up chopper circuit in order to convert the input voltage Vin into the output voltage Vout that is higher than the input voltage Vin. The step-up chopper circuit includes a choke coil L, a switching element Q1, a diode D1, and a capacitor C1. Specifically, a series circuit of the choke coil L1 and the switching element Q1 are connected between the input terminals +Vi and −Vi. A series circuit of the diode D1 and the capacitor C1 is connected between both terminals of the switching element Q1. The output terminals +Vo and −Vo are respectively connected to both terminals of the capacitor C1. The switching element Q1 is an N channel MOSFET (Metal Oxide Semiconductor Field Effect Transistor). However, the switching element Q1 is not limited to this and may be a semiconductor element with a control terminal, such as a bipolar transistor.

The voltage detection circuit 3 detects the output voltage Vout from the converter 2. The voltage detection circuit 3 is configured by connecting a series circuit of resistors R1 and R2 for dividing a voltage between the output terminals +Vo and −Vo. An analog detection voltage having a voltage value that is divided from the output voltage Vout is generated at a node between the resistors R1 and R2.

The microprocessor 4 corresponding to a digital circuit calculates a control command value, which is for stabilizing the output voltage Vout, by digital arithmetic. The microprocessor 4 includes an analog-to-digital converter (ADC) 11, a reference power supply 12, a central processing unit (CPU) 14, an I/O port 15, an operation clock 16, and a clock generation circuit 17.

The ADC 11 corresponds to an analog-to-digital conversion circuit in which a voltage value (analog detection voltage) from the voltage detection circuit 3 is converted into a digital value. Further, the reference power supply 12 generates a reference voltage as a reference signal that is used when the ADC 11 converts an analog value into a digital value.

The CPU 14 corresponds to an arithmetic circuit in which a digital control command value is calculated based on a digital signal obtained by the ADC 11, and then in which a difference value between an immediately preceding control command value and a present control command value calculated at the present time is calculated. Further, the I/O (Input and output) port 15 corresponds to a signal output circuit in which a high (H)-level signal or a low (L)-level signal is respectively output toward at least two or more charge terminals PH0, PH1, discharge terminals PL0, PL1 and toward terminals that generate at least two or more control signals S6, S7, S8 and S9 outside the microprocessor 4.

The operation clock 16 outputs a base clock signal for operating the CPU 14 at a predetermined cycle as an operation clock signal.

The clock generation circuit 17 is provided as a frequency divider in which a clock signal (synchronous clock signal) S1, which is obtained by dividing the operation clock signal from the operation clock 16, is output to outside the microprocessor 4. In the present embodiment, the operation clock signal of, for example, 8 MHz from the operation clock 16 is divided into a 1/16 frequency by the clock generation circuit 17. Then, the clock signal S1 of 500 kHz is sent to the ramp signal generation circuit 5. As a result, the clock signal S1 is for determining a frequency of a driving signal S5 as discussed later.

The clock generation circuit 17 according to the present embodiment divides the operation clock signal output from the operation clock 16 according to an instruction of the CPU 14. That is, the CPU 14 instructs the clock generation circuit 17 as to how many times to divide the operation clock signal. For example, the CPU 14 monitors an electric current that flows into a load (load current). Then, the CPU 14 gives the following instructions to the clock generation circuit 17. When the load current becomes smaller, make a frequency of the clock signal S1 lower. When the load current becomes larger, make a frequency of the clock signal S1 higher. As a result, the frequency of the clock signal S1 can be changed in accordance with the change of the load current. Further, the CPU 14 changes each current level of the control signals S6, S7, S8 and s9 from the I/O port 15 in accordance with changing frequency division.

The microprocessor 4 includes another clock generation circuit (not shown) that outputs a clock signal having a lower frequency than the clock signal S1 to the I/O port 15 by dividing the operation clock signal from the operation clock 16. In this embodiment, an operation clock signal of 8 MHz from the operation clock 16 is divided into a 1/256 frequency by another clock generation circuit. Then, the clock signal of 31.25 kHz is sent to the I/O port 15. Therefore, the I/O port 15 can send distinct and separate signals of 31.25 kHz to the pulse control circuit 6 toward each of discharge terminals PL0, PL1 and charge terminals PH0, PH1. Accordingly, the CPU 14 selects a new control command value every 256 clock cycles of an operation clock signal.

The ramp signal generation circuit 5 generates a serration-shaped or sawtooth wave signal S2 (ramp signal S2) based on the control signals S6, S7, S8 and S9 from the I/O port 15 and the clock signal S1 from the clock generation circuit 17. The ramp signal S2 that has the same frequency as the clock signal S1 is output to the pulse control circuit 6 from the ramp signal generation circuit 5.

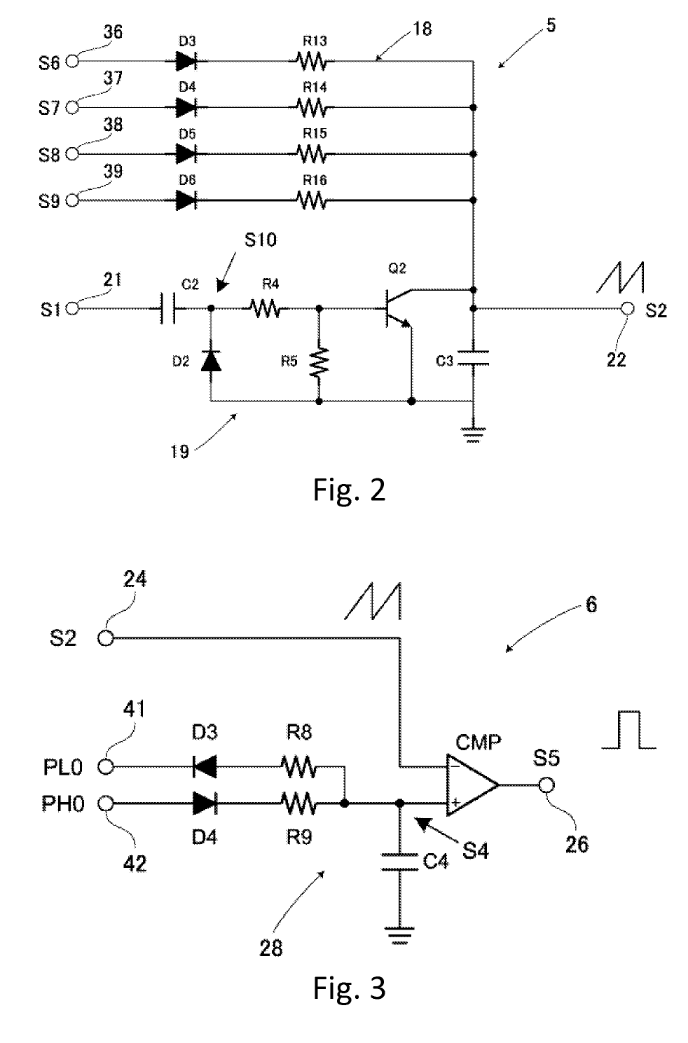

FIG. 2 is a circuit diagram of the ramp signal generation circuit 5. In FIG. 2, the ramp signal generation circuit 5 includes a charge circuit 18 instead of the resistor R6 of the conventional ramp signal generation circuit 100 shown in FIG. 10. The charge circuit 18 adjusts a peak value of a charge voltage of the capacitor C3 as a constant value regardless of a frequency of the clock signal S1. Further, the switch element Q2, the capacitor C2, the diode D2 and the resistors R4, R5 correspond to a discharge circuit 19. The discharge circuit 19 discharges the capacitor C3 in synchronization with a rising edge of the clock signal S1.

The charge circuit 18 is configured with first, second, third and fourth series circuits as discussed below. In the first series circuit, an anode of a diode D3 is connected to an input terminal 36 for a control signal S6, and a resistor R13 is connected between a cathode of the diode D3 and one end of the capacitor C3. In the second series circuit, an anode of the diode D4 is connected to an input terminal 37 for a control signal S7, and a resistor R14 is connected between a cathode of the diode D4 and the one end of the capacitor C3. In the third series circuit, an anode of a diode D5 is connected to an input terminal 38 for a control signal S8, and a resistor R15 is connected between a cathode of a diode D5 and the one end of the capacitor C3. In the fourth series circuit, an anode of a diode D6 is connected to an input terminal 39 for a control signal S9, and a resistor R16 is connected between a cathode of the diode D6 and the one end of the capacitor C3.

For example, when a cycle of the clock signal S1 is T1, the charge of the capacitor C3 is performed through the resistor R13 from the diode D3. Further, when a cycle of the clock signal S1 is T2, the charge of the capacitor C3 is performed through the resistor R14 from the diode D4. Yet further, when a cycle of the clock signal S1 is T3, the charge of the capacitor C3 is performed through the resistor R15 from the diode D5. Lastly, when a cycle of the clock signal S1 is T4, the charge of the capacitor C3 is performed through the resistor R16 from the diode D6. That is, as shown in table 1 below, when the cycle of the clock signal S1 is T1, only the control signal S6 becomes an H-level. When the cycle of the clock signal S1 is T2, only the control signal S7 becomes the H-level. When the cycle of the clock signal S1 is T3, only the control signal S8 becomes the H-level. When the cycle of the clock signal S1 is T4, only the control signal S9 becomes the H-level.

TABLE 1

| | Control | Control | Control | Control | Voltage Value of |
|---|---|---|---|---|---|
| | Signal | Signal | Signal | Signal | Ramp Signal S2 |
| Cycle | S6 | S7 | S8 | S9 | (Time Constant) |
| — | L | L | L | L | Lo (No Charging) |
| T4 | L | L | L | H | C*R₄ |
| T3 | L | L | H | L | C*R₃ |
| T2 | L | H | L | L | C*R₂ |
| T1 | H | L | L | L | C*R₁ |

Here, a capacitance value of the capacitor C3 is C. A resistance value of the resistor R13 is R₁. A resistance value of the resistor R14 is R₂. A resistance value of the resistor R15 is R₃. A resistance value of R16 is R₄. Further, a time constant is CR₁ when the cycle of the clock signal S1 is T1. A time constant is CR₂ when the cycle of the clock signal S1 is T2. A time constant is CR₃ when the cycle of the clock signal S1 is T3. A time constant is CR₄ when the cycle of the clock signal S1 is T4. The ramp signal generation circuit 5 ensures that the time constants CR₁-CR₄ respectively match with the peak voltage values of the ramp signal S2 at each cycle T1-T4. Table 1 above shows not only a relationship between the cycle of the clock signal S1 and an output theoretical value of the I/O port 15, but also a relationship between the cycle of the clock signal S1 and the time constants that determine a slope of a voltage increase of the ramp signal S2 (a charge voltage for the capacitor C3).

That is, each of the resistance values R₁, R₂, R₃ and R₄ for each of the resistors R13, R14, R15 and R16, respectively, is configured under the condition in which the following formula, T1/CR₁=T2/CR₂=T3/CR₃=T4/CR₄, is satisfied.

Referring back to FIG. 1, the pulse control circuit 6 outputs a driving signal S6, which has a pulse width based on an H-level signal toward the charge terminals PH0, PH1 and an L-level signal toward the discharge terminals PL0, PL1, to a gate as a control terminal of a switching element Q1 by the same cycle of the ramp signal S2 from the ramp signal generation circuit 5.

FIG. 3 is a circuit diagram of the pulse control circuit 6. FIG. 3 shows an exemplary circuit configuration in which the I/O port 15 shown in FIG. 1 has only one discharge and charge terminal including one discharge terminal PL0 and one charge terminal PH0. In FIG. 3, the pulse control circuit 6 is configured with a discharge and charge circuit 28 and a comparator CMP. The discharge and charge circuit 28 is configured with a capacitor C4, diodes D3, D4, and resistors R8, R9. Specifically, an inverting input terminal, which is one of the input terminals of the comparator CMP, is connected to an input terminal 24 for the ramp signal S2. A cathode of the diode D3 is connected to an input terminal 41 that is connected to the discharge terminal PL0 of the I/O port 15. An anode of the diode D4 is connected to an input terminal 42 that is connected to the charge terminal PH0 of the I/O port 15. One end of the resistor R8 is connected to an anode of the diode D3. One end of the resistor R9 is connected to a cathode of the diode D4. A non-inverting input terminal, which is another input terminal of the comparator CMP, is connected to a node connecting one end of the capacitor C4 and other ends of the resistors R8, R9. Another end of the capacitor C4 is connected to a ground potential line. An output terminal of the comparator CMP is connected to an output terminal 26 for the driving signal S5. The pulse control circuit 6 is configured with the above structure.

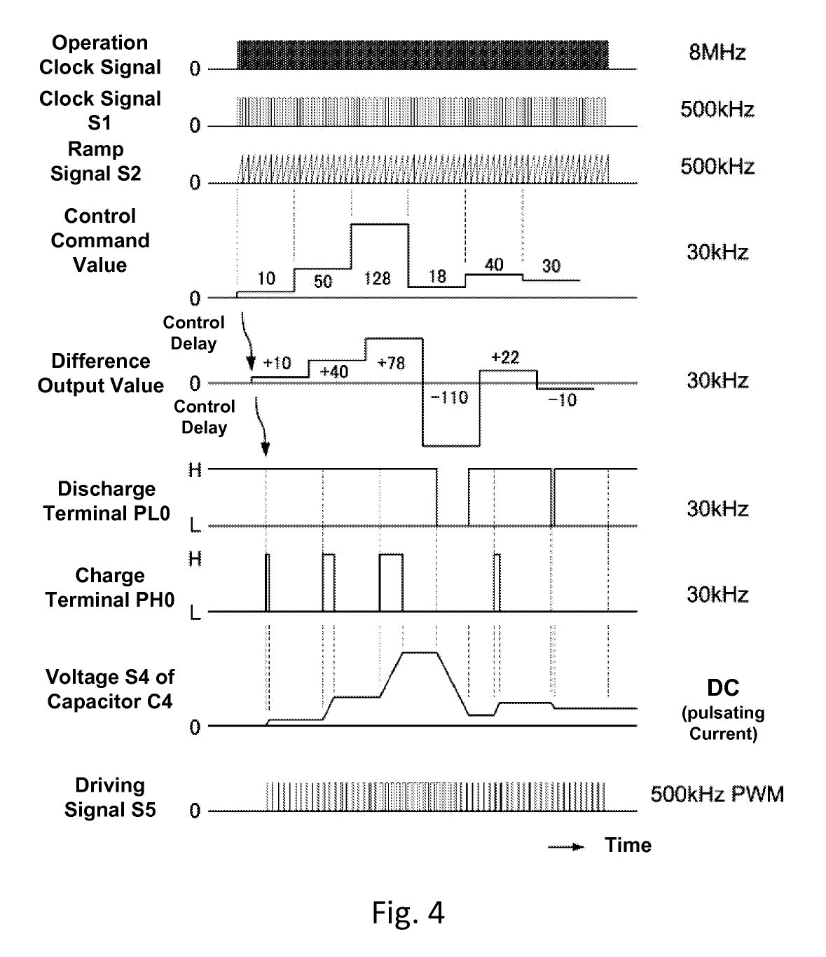

Next, functions of the above configuration are explained with reference to a timing diagram of each part shown in FIG. 4. In FIG. 4, the top one is the operation clock signal from the operation clock 16 followed by the clock signal S1, the ramp signal S2, the control command value generated by the CPU 14, a difference output value, a signal level of the discharge terminal PL0, a signal level of the charge terminal PH0, an end-to-end voltage S4 of the capacitor C4 (a voltage S4 between both terminals of the capacitor C4) shown in FIG. 3, and the driving signal S5.

When the pulsed driving signal S5 is given to a gate of the switching element Q1 from the pulse control circuit 6, the switching element Q1 repeats an ON and OFF operation. When the switching element Q1 is turned ON, the diode D1 is in an OFF state because an input voltage Vin is applied to a choke coil L1. Then, a discharge voltage, as an output voltage Vout, of the smoothing capacitor C1 is supplied to a load from output terminals +Vo, −Vo. When the switching element Q1 is turned OFF, the diode D1 is in an ON state because a reverse voltage of the choke coil L1 is overlapped with the input voltage Vin. Then, the output voltage Vout that is higher than the input voltage Vin is supplied to a load from the output terminals +Vo, −Vo and at the same time the capacitor C1 is charged through the diode D1.

The output voltage Vout from the converter 2 is monitored by the voltage detection circuit 3. The voltage detection circuit 3 provides an analog detection voltage that is obtained by dividing the output voltage Vout by the resistors R1, R2 to the ADC 11 of the microprocessor 4. The ADC 11 converts the analog detection voltage into a digital value by using a reference voltage from the reference power supply 12 and provides the digital value to the CPU 14.

The CPU 14 calculates a control command value based on a value of the detection voltage obtained by the voltage detection circuit 3 and the ADC 11. In this case, when the output voltage Vout becomes higher, the control command value becomes lower. In contrast, when the output voltage Vout becomes lower, the control command value becomes higher. The calculated control command value is temporarily stored in a memory (not shown) to calculate the difference output value. After the CPU 14 reads a previous control command value, which is calculated at the previous time, from the memory, the CPU 14 calculates a difference between a present control command value, which is calculated at the present time, and the previous control command value. The difference output value is calculated with a predetermined controlled delay with respect to the control command values, which are calculated at a predetermined cycle and is sent to the I/O port 15 from the CPU 14.

The I/O port 15 determines a period of outputting an H-level signal from the charge terminal PH0 and a period of outputting an L-level signal from the discharge terminal PL0. In this case, when the difference output value is positive, the H-level signal is output from the charge terminal PH0. In contrast, when the difference output value is negative, the L-level signal is output from the discharge terminal PL0. When the absolute value of the difference output value becomes larger, the period of outputting the H-level signal from the charged terminal PH0 or outputting the L-level signal from the discharge terminal PL0 becomes longer. In contrast, when the absolute value of the difference output value becomes smaller, the period of outputting the H-level signal from the charged terminal PH0 or outputting the L-level signal from the discharge terminal PL0 becomes shorter.

A clock signal of about 30 kHz, which is by dividing the operation clock signal from the operation clock 16 into a 1/256 frequency, is given to the I/O port 15. Thus, the I/O port 15 generates distinct and separate logic signals having the same frequencies as the clock signal for the charge terminals, such as PH0, and the discharge terminals, such as PL0. In order to achieve the above situation, the CPU 14 determines a new control command value and a difference output value at every frequency cycle. That frequency is the same as a frequency of the signal. In FIG. 4, the CPU 14 calculates each of the control command values, “10,” “50,” “128,” “18,” “40,” and “30,” in this order conforming to a frequency of the signal toward the charge terminal PH0 and the discharge terminal PL0. After the CPU 14 calculates the present control command value, the CPU 14 calculates the difference value (difference output value) between the current and previous control command values. In FIG. 4, the CPU 14 calculates each of the control command values, “+10,” “+40,” “+78,” “−110,” “+22,” and “−10,” in this order and outputs them to the I/O port 15. The I/O port 15 provides a signal to the pulse control circuit 6 from the microprocessor 4. This signal acts as follows: according to a duration that is in accordance with the absolute value of the difference output value, when the difference output value is positive, the charge terminal PH0 is switched to an H-level, and similarly when the difference output value is negative, the discharge terminal PL0 is switched to an L-level.

The microprocessor 4 provides the clock signal S1 from the clock signal generation circuit 17 and the control signals S6, S7, S8 and S9 from the I/O port 15 to the ramp signal generation circuit 5 in addition to the signals that are output toward the charge terminal PH0 and the discharge terminal PL0. The CPU 14 instructs the clock generation circuit 17 as to how many times to divide a frequency of the operation clock signal according to the change of a load current so as to decide a frequency of the clock signal S1. For instance, when the load current is small, the clock generation circuit 17 outputs the clock signal S1 of 250 kHz. This occurs by an instruction from the CPU 14 in which the operation clock signal of 8 MHz is divided into a 1/32 frequency so as to decrease the frequency of the clock signal S1. Further, when the load current is larger than the above situation, the clock generation circuit 17 outputs the clock signal S1 of 500 kHz. This occurs by an instruction from the CPU 14 in which the operation clock signal of 8 MHz is divided into a 1/16 frequency.

In addition, as shown in Table 1, the CPU 14 selectively makes one of the control signals S6, S7, S8 and S9 an H-level in accordance with a frequency (cycles T1, T2, T3 and T4) of the clock signal S1. Then, the CPU 14 outputs the selected control signal from the I/O port 15. As a result, a slope of the charge voltage increase for the capacitor C3 through the charge circuit 18 is determined. The CPU 14 selects the frequency of the clock signal S1 every 256 clock cycles (about 30 kHz cycle).

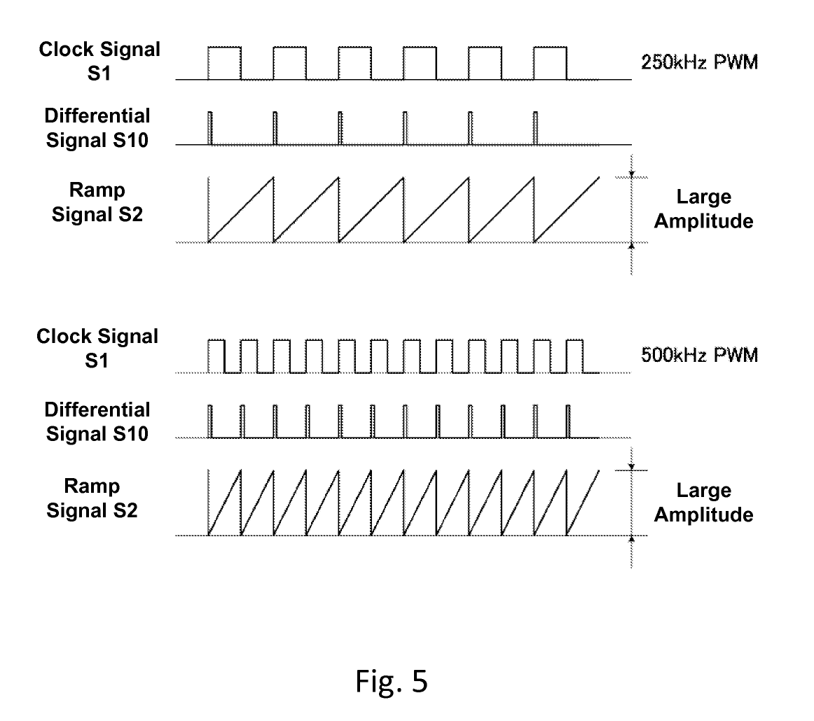

Next, an operation of the ramp signal generation circuit 5 is explained in detail with reference to the timing chart shown in FIG. 5. FIG. 5 shows each waveform of the differential signal S10 and the ramp signal S2 in the case in which frequencies of the clock signal S1 are 250 kHz and 500 kHz.

For instance, when the frequency of the clock signal S1 is 500 kHz, the CPU 14 instructs the clock generation circuit 17 to divide the operation clock signal into a 1/16 frequency. Then, the CPU 14 makes the control signal S6 an H-level and makes the other control signals S7, S8 and S9 L-levels through the I/O port 15. In the above case, the clock generation circuit 17 generates the clock signal S1 by the frequency of 500 kHz. In the discharge circuit 19, a trigger differential signal S10 for discharging the capacitor C3 in synchronization with a rising edge of the clock signal S1 is generated because the generated clock signal S1 above passes through the capacitor C2 of the discharge circuit 19. Further, because the charge circuit 18 charges the capacitor C3 from the diode D3 through the resistor R13, the charge voltage increases along a slope corresponding to the time constant C·R₁. Note that as explained above, the time constant that is obtained as the product of the resistor value (R₁) of the resistor R13 and a capacitance value (C) of the capacitor C3. Therefore, the ramp signal S2 of 500 kHz with a predetermined slope is generated at the output terminal 22 of the ramp signal generation circuit 5. Please refer to each waveform in the lower part of FIG. 5.

On the other hand, when a load current decreases, a frequency of the clock signal S1 is changed to, for example, 250 kHz. In this case, the CPU 14 instructs the clock generation circuit 17 to divide the operation clock signal into a 1/32 frequency. Then, the CPU 14 makes the control signal S7 an H-level and makes other control signals S6, S8 and S9 L-levels through the I/O port 15. In the above case, the clock generation circuit 17 generates the clock signal S1 by the frequency of 250 kHz. In the discharge circuit 19, a trigger differential signal S10 for discharging the capacitor C3 in synchronization with a rising edge of the clock signal S1 is generated because the generated clock signal S1 above passes through the capacitor C2 of the discharge circuit 19. Further, because the charge circuit 18 charges the capacitor C3 from the diode D4 through the resistor R14, the charge voltage increases along a slope corresponding to the time constant C·R₂. Similarly, as explained above, the time constant that is obtained as the product of the resistor value (R₂) of the resistor R14 and a capacitance value (C) of the capacitor C3. Therefore, the ramp signal S2 of 250 kHz is generated from the output terminal 22 of the ramp signal generation circuit 5. A slope of increase of the ramp signal S2 is gentler than the above ramp signal S2 of 500 kHz. In these cases, peak voltage values immediately before the capacitor C3 starts being discharged are constant regardless of the frequencies of the ramp signals S2. Please refer to each waveform in the upper part of FIG. 5.

When the clock signal S1 is generated by other frequencies that are different from the above frequencies, each of the resistance values R₁, R₂, R₃ and R₄ of the resistors R13, R14, R15 and R16 is configured to satisfy the following formula, T1/CR₁=T2/CR₂=T3/CR₃=T4/CR₄. Therefore, when a cycle of the clock signal S1 becomes longer, a time constant between the capacitor C3 and one of the resistors R13, R14, R15 and R16 becomes larger. In contrast, when the cycle of the clock signal S1 becomes shorter, the time constant becomes smaller. As a result, when a cycle of the clock signal S1 is changed, a peak voltage value of the ramp signal S2 maintains as a constant value. Because energy is required to perform discharging and charging operations for the capacitor C3 of the discharge circuit 19, a pull-up circuit connected to each of the input terminals 21, 36, 37, 38 and 39 is embedded in the I/O port 15 or the clock generation circuit 17.

Referring back to FIG. 4, in the discharge and charge circuit 28 of the pulse control circuit 6, when an H-level signal is output toward the charge terminal PH0, which is at least one of I/O ports of the microprocessor 4, the capacitor C4 is charged from the diode D4 through the resistor R9. Similarly, when an L-level signal is output toward the discharge terminal PL0, which is at least another I/O port of the microprocessor 4, the capacitor C4 is discharged from the resistor R8 through the diode D3. The input terminal 42 that is connected to the charge terminal PH0 and the capacitor C4 are connected to each other through the diode D4 and the resistor R9 that configure the charge circuit 18. In this case, when the H-level signal is output toward the charge terminal PH0, the capacitor C4 can be charged by connecting an anode of the diode D4 to the input terminal 42. The input terminal 41 that is connected to the discharge terminal PL0 and the capacitor C4 are connected to each other through the diode D3 and the resistor R8 that configure the discharge circuit 19. In this case, when the L-level signal is output toward the discharge terminal PL0, the capacitor C4 can be discharged by connecting a cathode of the diode D3 to the input terminal 41. Because energy is required to perform discharging and charging operations for the capacitor C4 of the discharge and charge circuit 28, a pull-up circuit connected to the charge terminal PH0 and a pull-down circuit connected to the discharge terminal PL0 are embedded in the I/O port 15.

As explained above, the end-to-end voltage S4, which is the output voltage of the discharge and charge circuit 28, of the capacitor C4 is adjusted based on the duration of the H-level signal toward the charge terminal PH0 and the duration of the L-level signal toward the discharge terminal PL0. Specifically, as shown in FIG. 4, the end-to-end voltage S4 linearly increases by charging the capacitor C4 during a period for which the H-level signal is output toward the charge terminal PH0. Similarly, the end-to-end voltage S4 linearly decreases by discharging the capacitor C4 during a period for which the L-level signal is output toward the discharge terminal PL0. The end-to-end voltage S4 is held without discharging and charging the capacitor C4 during a period for which the L-level signal is output toward the charge terminal PH0 and the H-level signal is output toward the discharge terminal PL0. The above duration for discharging and charging the capacitor C4 is determined based on a difference output value calculated by the CPU 14. Its variable step at most should be shorter than a cycle time of the operation clock signal. Table 2 is a transition table in which status of the end-to-end voltage S4 of the capacitor C4 are shown in relation to each logic level of the charge terminal PH0 and the discharge terminal PL0 in the pulse control circuit 6 shown in FIG. 3.

TABLE 2

| Charge | Discharge | Voltage S4 of |
|---|---|---|
| Terminal PH0 | Terminal PL0 | Capacitor C4 |
| L | L | Decrease |
| L | H | Hold |
| H | L | Non-Use |
| H | H | Increase |

The ramp signal S2 from the ramp signal generation circuit 5 is input to the inverting input terminal of the comparator CMP of the pulse control circuit 6. The end-to-end voltage S4, which is the output voltage of the discharge and charge circuit 28, of the capacitor C4 is input to the non-inverting input terminal of the comparator CMP. The comparator CMP sends the pulse driving signal S5 with a duty ratio that is based on the comparison result between the voltage value of the ramp signal S2 and the end-to-end voltage S4 of the capacitor C4 to the gate of the switching element Q1. Therefore, the switching element Q1 performs an ON and OFF operation so as to make the output voltage Vout from the converter 2 a constant value. In the above discussed series of operations, the following configurations may be used in order to make the output voltage Vout from the converter 2 a constant value. The ADC 11 is configured to increase a digital value when a voltage value from the voltage detection circuit 3 decreases. The CPU 14 is configured to increase a control command value when the digital value from the ADC 11 increases. Alternatively, the following configurations may be used in order to make the output voltage Vout from the converter 2 a constant value. The ADC 11 is configured to decrease the digital value when the voltage value from the voltage detection circuit 3 decreases. The CPU 14 is configured to increase the control command value when the digital value from the ADC 11 decreases.

A frequency of the driving signal S5 is the same as a frequency of the ramp signal S2. A pulse width of the driving signal S5 is adjusted by the end-to-end voltage S4 of the capacitor C4. In the pulse control circuit 6 shown in FIG. 3, when the end-to-end voltage S4 of the capacitor C4 increases by comparison with the voltage level of the ramp signal S2, the driving signal S5 of a long ON-duty ratio is generated. Thus, when the end-to-end voltage S4 of the capacitor C4 is higher, a pulse width of the driving signal S5 by which the switching element is turned ON is wider. A frequency of signals that are output toward the charge terminal PH0 and the discharge terminal PL0 may be lower than a frequency of the ramp signal S2.

In the present embodiment, because the microprocessor 4 controls with 8 bits, the output periods for an H-level signal toward the charge terminal PH0 and an L-level signal toward the discharge terminal PL0 are varied in a range of “(0 to 255) X cycle of operation clock signal (125 nanosecond(ns)).” These output periods for signals are determined based on the operation clock signal (8 MHz) form the operation clock 16 and are varied in periodic stages in increments of 125 ns. The end-to-end voltage S4 of the capacitor C4 increases or decreases based on the output periods of the signals. Then, this end-to-end voltage S4 and the ramp signal S2 are respectively input to the comparator CMP. Therefore, a pulse width of the driving signal S5 that is output from the comparator CMP can be changed every one pulse while the end-to-end voltage S4 of the capacitor C4 increases or decreases.

A frequency (for example, 500 kHz) of the driving signal S5 is determined in consideration of a size of the choke coil L1 and a loss of switching of the switching element Q1. This is because when a frequency decreases, the size of the choke coil L1 becomes large, and when the frequency increases, the loss of switching of the switching element Q1 increases. The clock generation circuit 17 does not divide the operation clock signal in a 1/16 frequency to secure a processing time for calculating a control command value by the CPU 14. Thus, a frequency of the clock signal S1 can be determined based on a specification of the converter 2.

In the present embodiment, a frequency of the operation clock signal is, for example, 500 kHz. However, the present embodiment is not limited to the above configuration to generate the operation clock signal of 500 kHz. For example, when the operation clock 16 also has functions of the clock generation circuit 17, a circuit configuration in which the driving signal S5 of 500 kHz remains the same can be realized. In this case, a frequency of a signal from the charge terminal PH0 and the discharge terminal PL0 is 1.95 kHz (500/256=1.95 kHz). It is preferred that the CPU 14 can calculate a new control command value every 256 clock cycles with respect to the operation clock signal so that it does not depend on a frequency of the operation clock signal.

FIG. 3 shows the pulse control circuit 6 that is provided with only one discharge and charge terminal including a pair including the discharge terminal PL0 and the charge terminal PH0. However, the pulse control circuit 6 is not limited to this configuration. The pulse control circuit 6 can be provided with two or more discharge and charge terminals including two or more pairs of two or more of the charge terminals PH0, PH1, . . . and two or more of the discharge terminals PL0, PL1, . . . . In this case, the end-to-end voltage S4 of the capacitor C4 can be more finely adjusted for a short period of time.

As discussed above, the ramp signal generation circuit 5 according to the present embodiment includes: the input terminal 21 as a first input terminal that receives the clock signal S1; the input terminals 36, 37, 38 and 39 as a plurality of second input terminals that receive H-level or L-level signals, respectively, in accordance with a cycle of the clock signal S1; the capacitor C3; and a discharge and charge circuit that discharges and charges the capacitor C3 and that outputs the ramp signal S2 corresponding to a voltage generated between both terminals of the capacitor C3. The discharge and charge circuit includes the discharge circuit 19 that discharges the capacitor C3 in synchronization with the clock signal S1, and the charge circuit 18 that is configured with a plurality of pairs of resistors R13, R14, R15 and R16 as resistor elements and diodes D3, D4, D5 and D6 as rectifying elements connected between the capacitor C3 and the plurality of input terminals 36, 37, 38 and 39. The charge circuit 18 charges the capacitor C3 through the resistors R13, R14, R15 and R16 and the diodes D3, D4, D5 and D6. The charge circuit 18 selects at least one of the plurality of input terminals 36, 37, 38 and 39 so as to change a value of a charge current for charging the capacitor C3 by inputting the H-level signal to the selected one of the plurality of input terminals.

Further, the ramp signal adjustment circuit of the present embodiment includes the clock signal generation circuit 17 that generates a clock signal S1 obtained by dividing an operation clock signal as a base clock signal and a plurality of terminals that connect to the input terminals 36, 37, 38 and 39, respectively, in addition to the ramp signal generation circuit 5 explained above. The ramp signal adjustment circuit further includes the I/O port 15 as a signal output circuit that outputs an H-level signal or an L-level signal toward each of the plurality of terminals in accordance with a cycle of the clock signal S1.

In this configuration, the plurality of input terminals 36, 37, 38 and 39 of the ramp signal generation circuit 5 are connected to a plurality of terminals of the clock signal generation circuit 17. At least one of the plurality of input terminals 36, 37, 38 and 39 is selected in accordance with a cycle of the clock signal S1 that is input to the input terminal 21. An H-level signal is input to the selected input terminal. Because the discharge circuit 19 discharges the capacitor C3 in synchronization with the clock signal S1, a frequency of the ramp signal S2 corresponds to a frequency of the clock signal S1. On the other hand, the charge circuit 18 changes a current value for charging the capacitor c3 so as to make a peak voltage value of the ramp signal S2 a predetermined value (constant) regardless of a cycle of the clock signal S1 by selectively switching respective pairs of the resistors R13, R14, R15 and R16 and the diodes D3, D4, D5 and D6 in which a charge current for the capacitor C3 flows. As a result, it is possible to provide the ramp signal generation circuit 5 and the ramp signal adjustment circuit that includes the ramp signal generation circuit 5 in which the peak voltage value of the ramp signal S2 is not changed even though a cycle of the ramp signal S2 is changed.

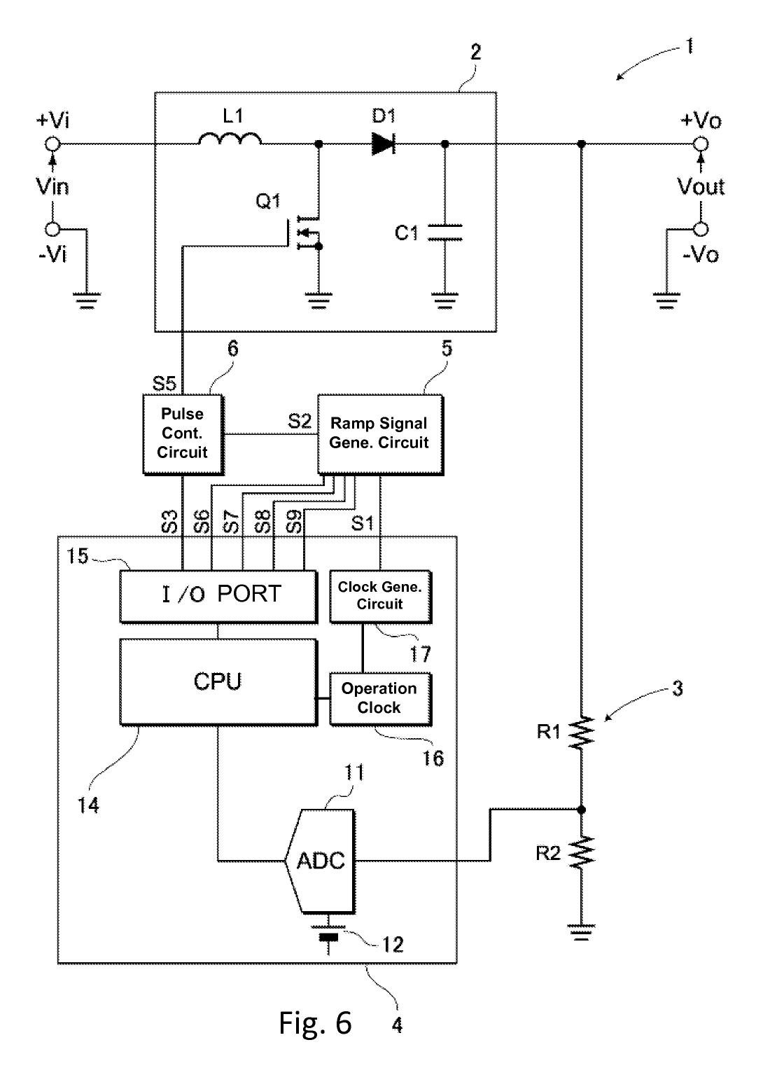

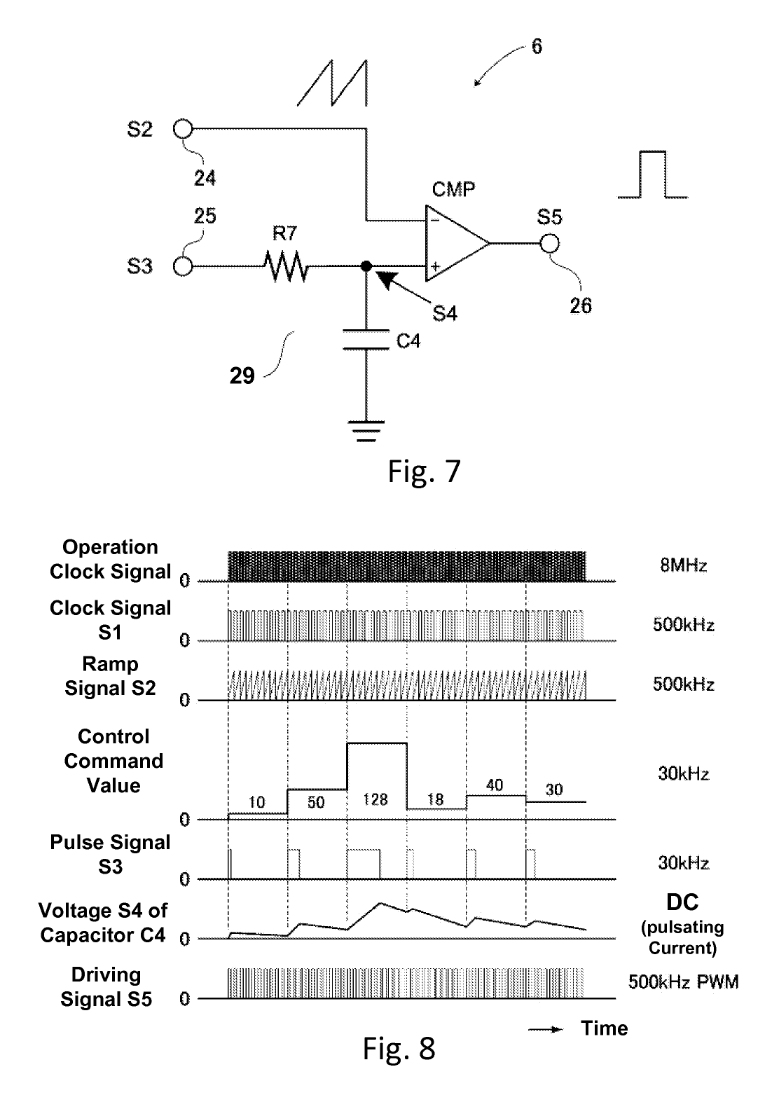

In the present embodiment, a construction of a power supply device shown in FIG. 6 and another example of a pulse control circuit 6 shown in FIG. 7 can be adopted. An I/O port 15 has a configuration in which the I/O port 15 outputs a pulse signal S3 with a duty ratio that is determined based on a control command value calculated by the microprocessor 4 to outside the microprocessor 4. Further, the pulse control circuit 6 is configured with a capacitor C4 and a resistor R7 that configure an integration circuit 29 and a comparator CMP. Specifically, an inverting input terminal, which is one of input terminals of the comparator CMP, is connected to an input terminal 24 for the ramp signal S2. One end of the resistor R7 that is an input terminal of the integration circuit 29 is connected to an input terminal 25 for the pulse signal S3. A non-inverting input terminal, which is another input terminal of the comparator CMP, is connected to a node connected between one end of the capacitor C4 and another end of the resistor R7 that is an output terminal of the integration circuit 29. Another end of the capacitor C4 is connected to a ground line. An output terminal of the comparator CMP is connected to an output terminal 26 for the driving signal S5. The pulse control circuit 6 is configured with the above structure.

FIG. 8 shows waveforms of each part of the power supply device shown in FIG. 6. In FIG. 8, the top one shows the operation clock signal from the operation clock 16 followed by the clock signal S1, the ramp signal S2, the control command value generated by the CPU 14, the pulse signal C3, the end-to-end voltage S4 of the capacitor C4 (a voltage S4 between both terminals of the capacitor C4) shown in FIG. 3 and the driving signal S5.

The CPU 14 calculate the control command value based on a value of a detection voltage that is obtained by a voltage detection circuit 3 and an ADC 11 in the power supply device shown in FIG. 6. In this case, when an output voltage Vout is high, the control command value is low. In contrast, when the output voltage Vout is low, the control command value is high. The I/O port 15 generates the pulse signal S3 in which a duty ratio is determined based on the control command value calculated by the CPU 14. In this case, when the control command value becomes larger, the duty ratio of the pulse signal S3 becomes larger. In contrast, as the control command value becomes smaller, the duty ratio of the pulse signal S3 becomes smaller.

A clock signal of about 30 kHz, which is obtained by dividing the operation clock signal from the operation clock 16 into a 1/256 frequency, is input to the I/O port 15. Thus, the I/O port 15 generates the pulse signal S3 that has the same frequency as the clock signal. Thus, the CPU 14 determines a new control command value at every frequency cycle. That frequency is the same as the pulse signal S3. In FIG. 8, the CPU 14 calculates each of the control command values, “10,” “50,” “128,” “18,” “40,” and “30,” in this order conforming to a frequency of the pulse signal S3. Then, the I/O port 15 generates the pulse signal S3 having duty ratios corresponding to those control command values. The pulse signal S3 is sent to the pulse control circuit 6 from the microprocessor 4.

The pulse signal S3 is input to the integration circuit 29 of the pulse control circuit 6. The end-to-end voltage S4 of the capacitor C4, which is an output voltage of the integration circuit 29, increases and decreases in accordance with the duty ratio of the pulse signal S3. In this case, as shown in FIG. 8, the end-to-end voltage S4 depends on time constants of the resistor R7 and the capacitor C4, which configure the integration circuit 29. Thus, when the pulse signal S3 becomes an H-level, the end-to-end voltage S4 increases. When the pulse signal S3 becomes an L-level, the end-to-end voltage S4 decreases. As a result, the end-to-end voltage S4 constantly varies within one cycle of the fixed pulse signal S3. When the duty ratio of the pulse signal S3 becomes larger, a time for increasing the end-to-end voltage S4 becomes longer and then a time for decreasing the end-to-end voltage S4 becomes shorter after the increase. Because energy is required to perform discharging and charging operations for the capacitor C4 of the integration circuit 29, a pull-up circuit or a pull-down circuit connected to the input terminal 25 is embedded in the I/O port 15. The above duration for discharging and charging the capacitor C4 is determined based on a control command value calculated by the CPU 14. The longest variable step should be shorter than a cycle time of the operation clock signal.

The ramp signal S2 from the ramp signal generation circuit 5 is input to the inverting input terminal of the comparator CMP of the pulse control circuit 6. The end-to-end voltage S4, which is the output voltage of the integration circuit 29, of the capacitor C4 is input to the non-inverting input terminal of the comparator CMP. The comparator CMP sends the pulse driving signal S5 with a duty ratio that is based on the comparison result between the voltage value of the ramp signal S2 and the end-to-end voltage S4 of the capacitor C4 to the gate of the switching element Q1. Therefore, the switching element Q1 performs an ON and OFF operation so as to make the output voltage Vout from the converter 2 a constant value.

The configuration of the I/O port 15 having output terminals that output the control signals S6, S7, S8 and S9 and the configuration of the ramp signal generation circuit 5 that receives the control signals S6, S7, S8 and s9 are the same as described above. Therefore, even though the cycle of the ramp signal S2 is changed, it is possible to provide the ramp signal generation circuit 5 and the ramp signal adjustment circuit including the ramp signal generation circuit 5 in which a peak voltage value of the ramp signal S2 is not changed.

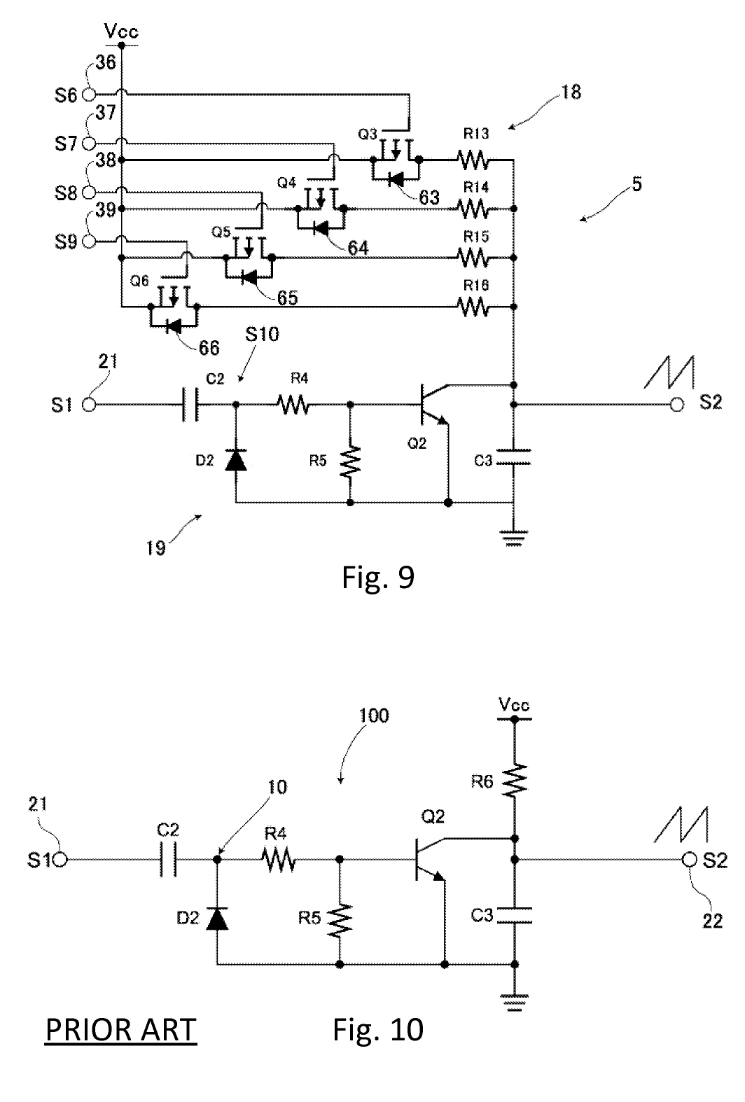

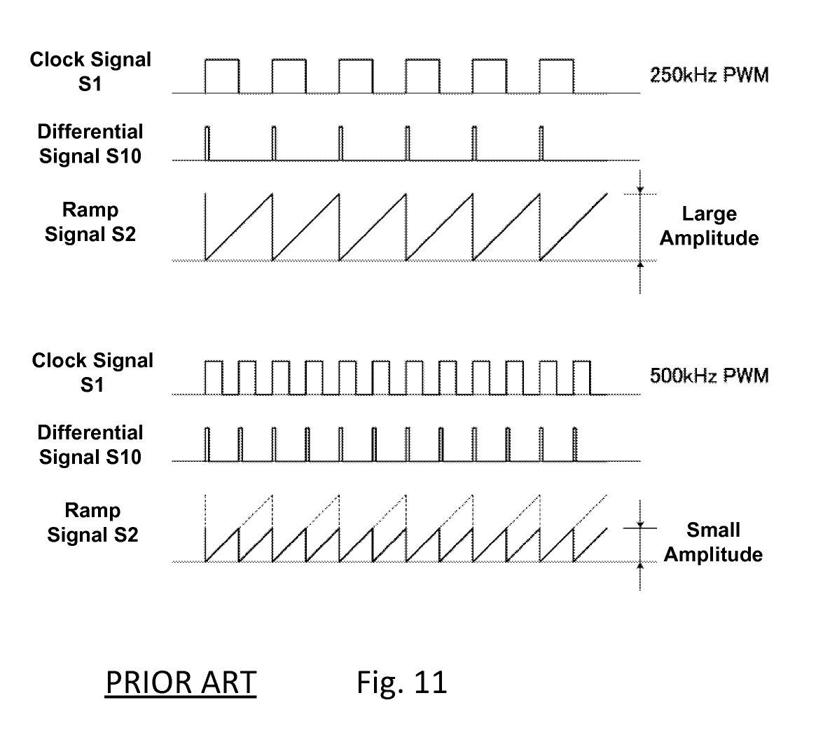

Further, the configuration of the ramp signal generation circuit 5 can be different than FIG. 2. FIG. 9 shows another circuit diagram of the ramp signal generation circuit 5. With respect of a charge circuit 18 as a charge voltage adjustment circuit, the resistors R13, R14, R15 and R16 are connected to a line of the power supply voltage Vcc that is generated by an internal electrical power source (not shown) through the switching elements Q3, Q4, Q5 and Q6. In other words, the charge circuit 18 is configured with first, second, third and fourth series circuits. In the first series circuit, a source of the switching element Q3 is connected to a line of the power supply voltage Vcc and the resistor R13 is connected between a drain of the switching element Q3 and one end of the capacitor C3. In the second series circuit, a source of the switching element Q4 is connected to the line of the power supply voltage Vcc and the resistor R14 is connected between a drain of the switching element Q4 and the one end of the capacitor C3. In the third series circuit, a source of the switching element Q5 is connected to the line of the power supply voltage Vcc and the resistor R15 is connected between a drain of the switching element Q5 and the one end of the capacitor C3. In the fourth series circuit, a source of the switching element Q6 is connected to the line of the power supply voltage Vcc and the resistor R16 is connected between a drain of the switching element Q6 and the one end of the capacitor C3. Further, the input terminal 36 for the control signal S6 is connected to a gate, which is a control terminal, of the switching element Q3. The input terminal 37 for the control signal S7 is connected to a gate, which is a control terminal, of the switching element Q4. The input terminal 38 for the control signal S8 is connected to a gate, which is a control terminal, of the switching element Q5. The input terminal 39 for the control signal S9 is connected to a gate, which is a control terminal, of the switching element Q6. Therefore, a charge current for the capacitor C3 flows in only a resistor among the resistors R13, R14, R15 and R16 that is connected to a switching element, which is turned on, among the switching elements Q3, Q4, Q5 and Q6.

The switching elements Q3, Q4, Q5 and Q6 are all P-channel MOSFETs. A switching element, in which an L-level signal is given to a gate, among the switching elements Q3, Q4, Q5 and Q6 is turned ON. For example, when a cycle of the clock signal S1 is T1, only the control signal S6 becomes an L-level. When the cycle of the clock signal S1 is T2, only the control signal S7 becomes the L-level. When the cycle of the clock signal S1 is T3, only the control signal S8 becomes the L-level. When the cycle of the clock signal S1 is T4, only the control signal S9 becomes the L-level. That is, logic-levels between Table 1 and the above embodiment are completely opposite. However, each resistance value R₁, R₂, R₃ and R₄ of the resistors R13, R14, R15 and R16 is configured so that the following formula, T1/CR₁=T2/CR₂=T3/CR₃=T4/CR₄, is satisfied. Therefore, even in this embodiment, a peak voltage value of the ramp signal S2 is constant regardless of a frequency of the ramp signal S2.

Note that when the switching elements Q3, Q4, Q5 and Q6 are MOSFETs, diodes 63, 64, 65 and 66 that allow a current flow from drains to sources are respectively formed in each of the MOSFETs.

As discussed above, the ramp signal generation circuit 5 according to the present embodiment includes: the input terminal 21 as a first input terminal that receives the S1 clock signal; the input terminals 36, 37, 38 and 39 as a plurality of second input terminals that receive H-level or L-level signals, respectively, in accordance with a cycle of the clock signal S1; the capacitor C3; and a discharge and charge circuit that discharges and charges the capacitor C3 and that outputs the ramp signal S2 corresponding to a voltage generated between both terminals of the capacitor C3. The discharge and charge circuit includes the discharge circuit 19 that discharges the capacitor C3 in synchronization with the clock signal S1. The discharge and charge circuit also includes the charge circuit 18 that is configured with a plurality of paired resistors R13, R14, R15 and R16 and the switching elements Q3, Q4, Q5 and Q6 connected between the capacitor C3 and the power source voltage line Vcc. The charge circuit 18 charges the capacitor C3 through one of the resistors R13, R14, R15 and R16 and one of the switching elements Q3, Q4, Q5 and Q6. The charge circuit 18 selects at least one of the plurality of input terminals 36, 37, 38 and 39 so as to change a value of a charge current for charging the capacitor C3 through an ON and OFF operation of the switching elements Q3, Q4, Q5 and Q6 by inputting the high-level signal to the selected one of the plurality of input terminals.

Further, the ramp signal adjustment circuit of the present embodiment includes the clock signal generation circuit 17 that generates a clock signal S1 obtained by dividing an operation clock signal as a base clock signal and a plurality of terminals that connect to the input terminals 36, 37, 38 and 39, respectively, in addition to the ramp signal generation circuit 5 explained above. The ramp signal adjustment circuit further includes the I/O port 15 as a signal output circuit that outputs an H-level signal or an L-level signal toward each of the plurality of terminals in accordance with a cycle of the clock signal S1.

In this configuration, the plurality of input terminals 36, 37, 38 and 39 of the ramp signal generation circuit 5 are connected to a plurality of terminals of the clock signal generation circuit 17. At least one of the plurality of input terminals 36, 37, 38 and 39 is selected in accordance with a cycle of the clock signal S1 that is input to the input terminal 21. An H-level signal is input to the selected input terminal. Because the discharge circuit 19 discharges the capacitor C3 in synchronization with the clock signal S1, a frequency of the ramp signal S2 corresponds to a frequency of the clock signal S1. On the other hand, the charge circuit 18 changes a current value for charging the capacitor c3 so as to make a peak voltage value of the ramp signal S2 a predetermined value (constant) regardless of a cycle of the clock signal S1 by selectively switching respective pairs of the resistors R13, R14, R15 and R16 and the switching elements Q3, Q4, Q5 and Q6 in which a charge current for the capacitor C3 flows. As a result, it is possible to provide the ramp signal generation circuit 5 and the ramp signal adjustment circuit that includes the ramp signal generation circuit 5 in which the peak voltage value of the ramp signal S2 is not changed even though a cycle of the ramp signal S2 is changed.

Embodiments according to the present invention have been explained. However, the present invention should not be limited to the embodiments because those embodiments are simply examples for explaining the present invention. Undoubtedly, several modifications may be made without departing from the spirit and scope of the invention. For example, the ramp signal generation circuit 5 and the ramp signal adjustment circuit that are explained in the present embodiments are not limited to a step-up chopper circuit as shown in the drawings. They can be applied to a power supply device that has any converter 2 of any circuit configuration. If a load is one or more light emitting elements, a current detection circuit can be included instead of the voltage detection circuit 3 in order to make an output current flowing in the light emitting element constant. Thus, the present invention can be applied to a light emitting element drive device in which a current feedback loop is formed for the converter 2. Further, the present invention can be applied to various types of circuit devices other than power supply devices and light emitting element drive devices. Signal levels, frequencies (cycles), logic configurations of each part discussed in the above embodiments may be changed.

In the above embodiments, at least one of the plurality of input terminals 36, 37, 38 and 39 is selected in accordance with a cycle of the clock signal S1. However, the present invention is not limited to this. Further to the above applications, at least two of the plurality of input terminals 36, 37, 38 and 39 may be selected in accordance with a cycle of the clock signal S1. Then, a charge current is supplied to the capacitor C3 from the charge circuit 18 by inputting H-level signals to the selected at least two input terminals. In this case, the capacitor C3 can be charged so as to make a peak voltage value of the ramp signal S2 a predetermined value (constant) regardless of a cycle of the clock signal S1.

The ramp signal generation circuit and the ramp signal adjustment circuit being thus described, it will be apparent that the same may be varied in many ways. Such variations are not to be regarded as a departure from the spirit and scope of the invention, and all such modifications as would be apparent to one of ordinary skill in the art are intended to be included within the scope of the following claims.

What is claimed is:

1. A ramp signal generation circuit, comprising:
a first input terminal that receives a clock signal;
a plurality of second input terminals that receive high-level or low-level signals, respectively, in accordance with a cycle of the clock signal;
a capacitor; and
a discharge and charge circuit that discharges and charges the capacitor and that outputs a ramp signal corresponding to a voltage generated by the capacitor, the discharge and charge circuit including:
a discharge circuit that discharges the capacitor in synchronization with the clock signal; and
a charge circuit that is configured with a plurality of paired resistors and rectifying elements connected between the capacitor and the plurality of second input terminals, the charge circuit charging the capacitor through the resistor and the rectifying element, wherein
the discharge and charge circuit selects at least one of the plurality of second input terminals so as to change a value of a charge current for charging the capacitor by inputting the high-level signal to the selected one of the plurality of second input terminals.

2. The ramp signal generation circuit according to claim 1, wherein
when the discharge circuit discharges the capacitor, a frequency of the ramp signal corresponds to a frequency of the clock signal.

3. The ramp signal generation circuit according to claim 1, wherein
when the charge circuit charges the capacitor, a peak voltage value of the ramp signal is kept constant regardless of the cycle of the clock signal by switching the pair connected between the capacitor and the plurality of second input terminals.

4. The ramp signal generation circuit according to claim 3, wherein
when a cycle of the ramp signal is changed, the peak voltage value of the ramp signal is constant.

5. A ramp signal generation circuit, comprising:
a first input terminal that receives a clock signal;
a plurality of second input terminals that receive high-level or low-level signals, respectively, in accordance with a cycle of the clock signal;
a capacitor; and
a discharge and charge circuit that discharges and charges the capacitor and that outputs a ramp signal corresponding to a voltage generated by the capacitor, the discharge and charge circuit including:
a discharge circuit that discharges the capacitor in synchronization with the clock signal; and
a charge circuit that is configured with a plurality of paired resistors and switching elements connected between the capacitor and a power source voltage line, the charge circuit charging the capacitor through one of the resistors and one of the switching elements, wherein
the discharge and charge circuit selects at least one of the plurality of second input terminals so as to change a value of a charge current for charging the capacitor through an ON and OFF operation of the switching elements by inputting the high-level signal to the selected one of the plurality of second input terminals.

6. The ramp signal generation circuit according to claim 5, wherein
when the discharge circuit discharges the capacitor, a frequency of the ramp signal corresponds to a frequency of the clock signal.

7. The ramp signal generation circuit according to claim 5, wherein
when the charge circuit charges the capacitor, a peak voltage value of the ramp signal is kept constant regardless of the cycle of the clock signal by switching the pair connected between the capacitor and the power source voltage line.

8. The ramp signal generation circuit according to claim 7, wherein
when a cycle of the ramp signal is changed, the peak voltage value of the ramp signal is constant.

9. A ramp signal adjustment circuit, comprising:
a clock signal generation circuit that generates a clock signal by dividing a base clock signal;
a signal output circuit that has a plurality of terminals and that outputs high-level or low-level signals from each of the plurality of terminals;
a capacitor; and
a discharge and charge circuit that discharges and charges the capacitor and that outputs a ramp signal corresponding to a voltage generated by the capacitor, the discharge and charge circuit including:
a discharge circuit that discharges the capacitor in synchronization with the clock signal; and
a charge circuit that is configured with a plurality of paired resistors and rectifying elements connected between the capacitor and the plurality of terminals, the charge circuit charging the capacitor through one of the resistors and one of the rectifying elements, wherein
the discharge and charge circuit selects at least one of the plurality of terminals so as to change a value of a charge current for charging the capacitor by inputting the high-level signal to the selected one of the plurality of terminals.

10. The ramp signal adjustment circuit according to claim 9, wherein
when the discharge circuit discharges the capacitor, a frequency of the ramp signal corresponds to a frequency of the clock signal.

11. The ramp signal adjustment circuit according to claim 9, wherein
when the charge circuit charges the capacitor, a peak voltage value of the ramp signal is kept constant regardless of a cycle of the clock signal by switching the pair connected between the capacitor and the plurality of terminals.

12. The ramp signal adjustment circuit according to claim 11, wherein
when a cycle of the ramp signal is changed, the peak voltage value of the ramp signal is constant.

13. A ramp signal adjustment circuit, comprising:
a clock signal generation circuit that generates a clock signal by dividing a base clock signal;
a signal output circuit that has a plurality of terminals and that outputs high-level or low-level signals from each of the plurality of terminals;
a capacitor; and
a discharge and charge circuit that discharges and charges the capacitor and that outputs a ramp signal corresponding to a voltage generated by the capacitor, the discharge and charge circuit including:
a discharge circuit that discharges the capacitor in synchronization with the clock signal; and
a charge circuit that is configured with a plurality of paired resistors and switching elements connected between the capacitor and a power source voltage line, the charge circuit charging the capacitor through one of the resistors and one of the switching elements, wherein
the discharge and charge circuit selects at least one of the plurality of terminals so as to change a value of a charge current for charging the capacitor through an ON and OFF operation of the switching elements by inputting the high-level signal to the selected one of the plurality of terminals.

14. The ramp signal adjustment circuit according to claim 13, wherein
when the discharge circuit discharges the capacitor, a frequency of the ramp signal corresponds to a frequency of the clock signal.

15. The ramp signal adjustment circuit according to claim 13, wherein
when the charge circuit charges the capacitor, a peak voltage value of the ramp signal is kept constant regardless of a cycle of the clock signal by switching the pair connected between the capacitor and the power source voltage line.

16. The ramp signal adjustment circuit according to claim 15, wherein
when a cycle of the ramp signal is changed, the peak voltage value of the ramp signal is constant.
